(19) United States
(12) Patent Application Publication
(10) Pub. No.: US 2016/0093767 A1
(43) Pub. Date: Mar. 31, 2016

(54) LIGHT EMITTING DIODE AND METHOD FOR MANUFACTURING THE SAME

(71) Applicant: ADVANCED OPTOELECTRONIC TECHNOLOGY, INC., Hsinchu Hsien (TW)

(72) Inventors: CHING-HSUEH CHIU, Hukou (TW); YA-WEN LIN, Hukou (TW); PO-MIN TU, Hukou (TW); SHIH-CHENG HUANG, Hukou (TW)

(21) Appl. No.: 14/814,744

(22) Filed: Jul. 31, 2015

(30) Foreign Application Priority Data
Sep. 29, 2014 (CN) 201410510986.7

(51) Int. Cl. H01L 33/20; H01L 33/00; H01L 33/12

(52) U.S. Cl. CPC H01L 33/20; H01L 33/12; H01L 33/0025; H01L 33/0075; H01L 33/0095; H01L 2933/0083

(57) ABSTRACT

A light emitting diode includes a base and a semiconductor structure mounted on the base. The base includes a substrate that has a first surface and a second surface located opposite to the first surface. The first surface of the substrate forms a microstructure. The bottom of the microstructure covers the first surface. The microstructure is a plurality of mental portion bended continuously and includes a plurality of protruding structures. A top surface of each protruding structure is a flat plate. A method for manufacturing the light emitting diode is also provided.

### CROSS-REFERENCE TO RELATED APPLICATIONS

This application claims priority to Chinese Patent Application No. 201410510986.7 filed on Sep. 29, 2014, the contents of which are incorporated by reference herein.

### FIELD

The subject matter herein generally relates to a light emitting diode (LED), and also relates to a method for manufacturing the same.

### BACKGROUND

A light emitting diode generally includes a substrate, an N semiconductor layer, a light emitting layer, and a P semiconductor layer arranged on the substrate in series. An N electrode is mounted on the N semiconductor layer, and a P electrode is mounted on the P semiconductor layer. While the LED is manufactured, a plurality of protrusions is firstly formed on the substrate, the N semiconductor layer, a light emitting layer and a P semiconductor layer are formed on the substrate.

### BRIEF DESCRIPTION OF THE DRAWINGS

Implementations of the present technology will now be described, by way of example only, with reference to the attached figures.

FIG. 1 is a cross sectional view of a light emitting diode in accordance with a first embodiment of the present disclosure.

FIG. 2 is a cross sectional view of a substrate of the light emitting diode in FIG. 1.

FIG. 3 is a flow chart of a method for forming a light emitting diode in accordance with the present disclosure.

FIGS. 4-9 are diagrammatic cross sections showing the light emitting diode of the first embodiment of the present disclosure processed by various steps of the light emitting diode method of FIG. 3.

FIG. 10 is a top view of the substrate of the light emitting diode of the first embodiment of the present disclosure.

FIG. 11 is a top view of a substrate of a light emitting diode of a second embodiment of the present disclosure.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. The description is not to be considered as limiting the scope of the embodiments described herein.

The term “comprising” means “including, but not necessarily limited to”; it specifically indicates open-ended inclusion or membership in a so-described combination, group, series and the like.

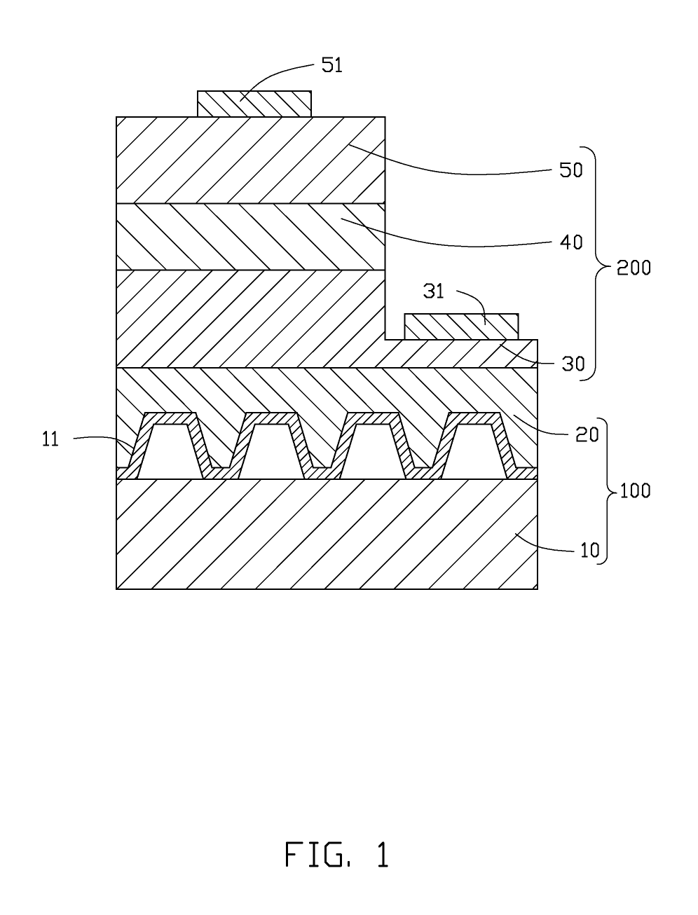

As illustrated in FIG. 1, a light emitting diode of a first embodiment includes a base 100 and a semiconductor structure 200 mounted on the base 100. The base 100 includes a substrate 10 and a buffer layer 20 mounted on the substrate 10.

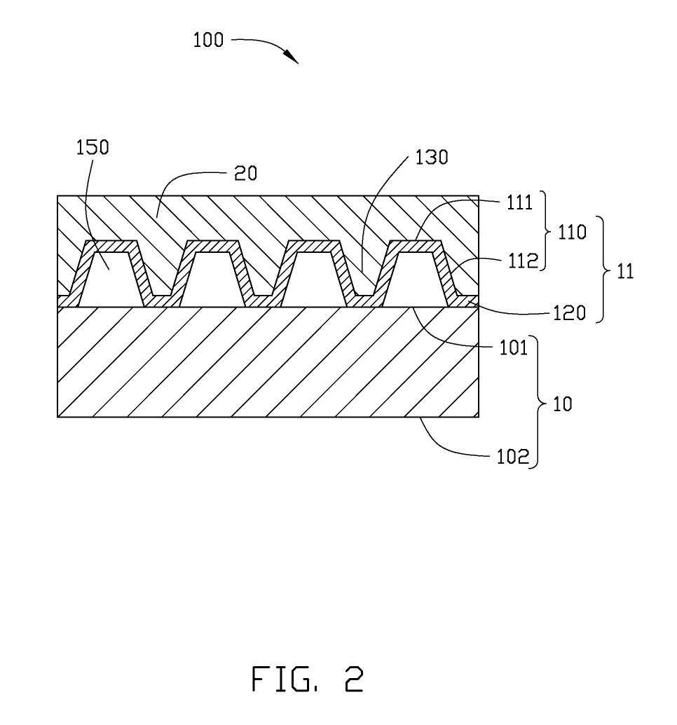

As illustrated in FIG. 2, the substrate 10 is made of sapphire, silicon material, or Gallium nitride. In the illustrated embodiment, the substrate 10 is made of sapphire. The substrate 10 includes a first surface 101 and a second surface 102 located opposite to the first surface 101. A microstructure 11 is formed on the first surface 101 of the substructure 10.

The microstructure 11 can be a strip bended continuously, and includes a plurality of protruding portions 110 and a plurality of connecting portions 120 connecting to the protruding portions 110. A thickness of the strip along a length direction thereof can be uniform. The thickness of the strip along a length direction thereof is between 80 nm and 180 nm, in one example, the thickness of the strip along a length direction thereof is 120 nm. A plurality of void gaps 150 are sandwiched between the microstructure 11 and the substrate 10. Each void gap is surrounded by a corresponding protruding portion 110 and the substrate 10. Each protruding portion 110 includes a top wall 111 and two side walls 112 extending outward and downward from the top wall 111. Each void gap is defined by the top wall 111 and the two sides walls 112. A size of the protruding portion 110 gradually decreases from the first surface 101 of the substrate 10 to the connecting portion 120. Each bottom end of one of side walls 112 connects with a corresponding connecting portion 120. Two adjacent side walls 112 of each protruding portion 110 and one connecting portion 120 therebetween define a groove 130. Each top wall 111 is a flat plate.

In the illustrated embodiment, the microstructure 11 is made of Aluminum nitride (AlN). The top walls 111 of the protruding portion 110 are coplanar with each other. The connecting portions 120 of the microstructure 11 are also coplanar with each other. The microstructure 11 completely covers the first surface 101 of the substrate 10. The top walls 111 are parallel plate for reducing the stress between the microstructure 11 and the semiconductor layer 200 and improving quality of the LED. Further, the protruding portion 110 can reflect light emitted from the semiconductor layer 200 to improve the luminous efficiency of the LED.

A buffer layer 20 is filled in the groove 130 to cover the microstructure 11. The buffer layer 20 can reduce the lattice defects of an N semiconductor layer 30. A refractive index of the buffer 20 is greater than that of the microstructure 11.

The semiconductor layer 200 includes an N semiconductor layer 30, a light emitting layer 40 and a P semiconductor layer 50 mount on the buffer layer 20 of the base 100. An N electrode 31 is mounted on the N semiconductor layer 30, and a P electrode 51 is mounted on the P semiconductor layer 50. The P semiconductor layer 50 is made of Gallium nitride (GaN) and provides holes. The N semiconductor layer 30 is made of doped Gallium nitride (GaN) and provides electrons. The light emitting layer 40 gathers holes from the P semiconductor layer 50 and electrons from the N semiconductor layer 30 together to emit light.

In the illustrated embodiment, the microstructure 11 of the LED avoids the lattice defect density between the base 100 and the semiconductor layer 200. Also, the refractive index of the buffer layer 20 is greater than that of the microstructure 11 such that the light emitted from the light emitting layer 40 towards the base 100 can be totally reflected at the microstructure 11 to emit towards the direction away the base 100. Thus, the light exit from the second surface 102 of the base 100 is limited, and the light exit towards the P semiconductor layer 50 is increased to improve the luminous efficiency of the LED.

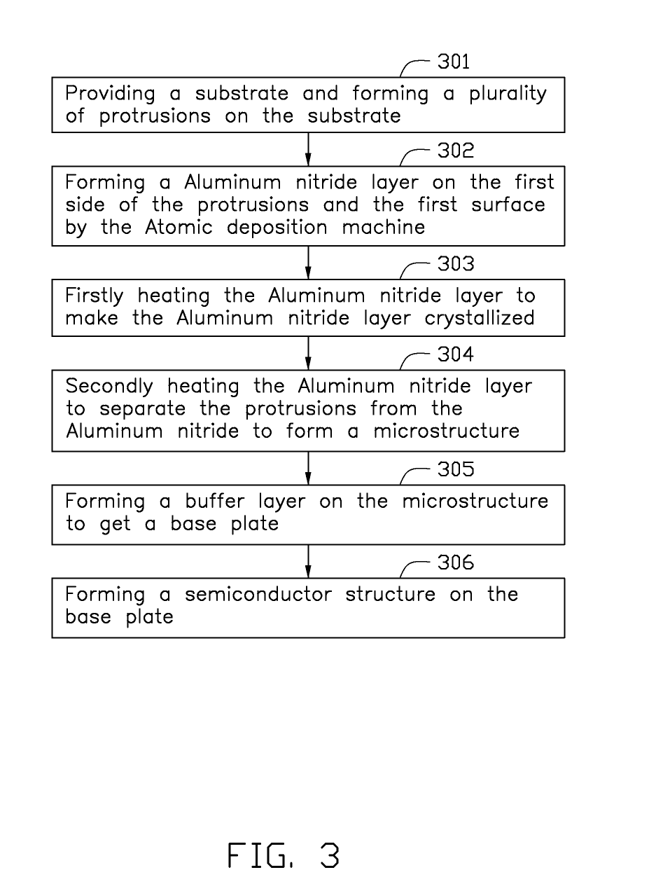

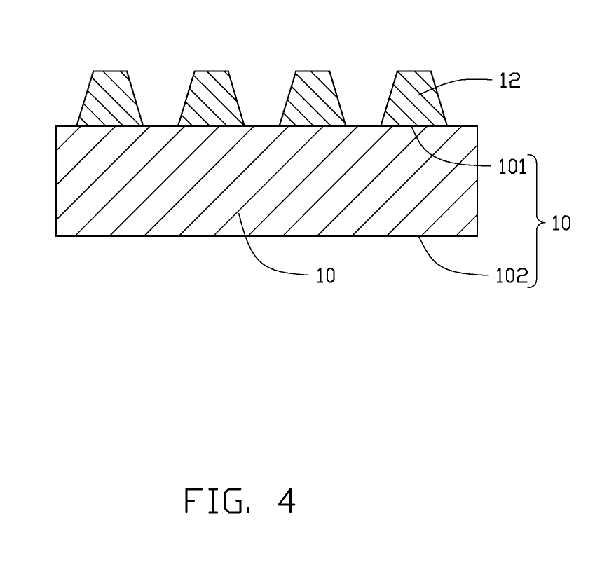

FIG. 3 illustrates a flow chart of a method for forming a light emitting diode in accordance with the embodiment of the present disclosure. The example method is provided by way of example, as there are a variety of ways to carry out the method. The method described below can be carried our using the configurations illustrated in FIGS. 4-9, for example, and various elements of these figures are reference in explaining example method. Each block shown in FIG. 3 represents one or more processes, methods or subroutines, carried out in the example method. Additionally, the illustrated order of block is by example only and the order of the blocks can change according to the present disclosure. The example method can begin at block 301.

At block 301, referring to FIG. 4, providing a substrate 10, and forming a plurality of protrusions 12 on the first side 101 of the substrate 10 by sputtering technology. The protrusions 12 are made of light resistance agents.

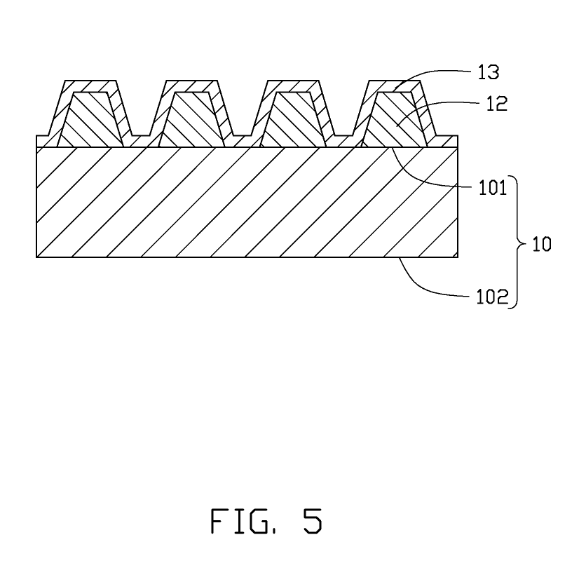

At block 302, referring to FIG. 5, forming an Aluminum nitride layer 13 on the first side 101 and the protrusions 12 by the Atomic deposition machine. In the illustrated disclosure, The Aluminum nitride layer 13 can be a strip bended continuously. A thickness of the strip along a length direction thereof is uniform and configured between 80 nm and 180 nm, in one example, the thickness of the strip along a length direction thereof is 120 nm.

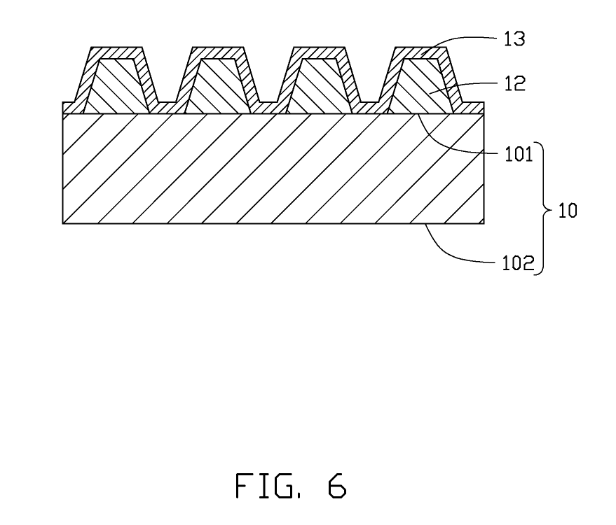

At block 303, referring to FIG. 6, firstly heating the Aluminum nitride layer 13 to crystallize the Aluminum nitride layer 13 to be stable. In the illustrated disclosure, the heating temperature is between 700° and 950°, the firstly heating time is between 70 minutes and 100 minutes. In one example, the firstly heating temperature is 800°, and the firstly heating time is 90 minutes.

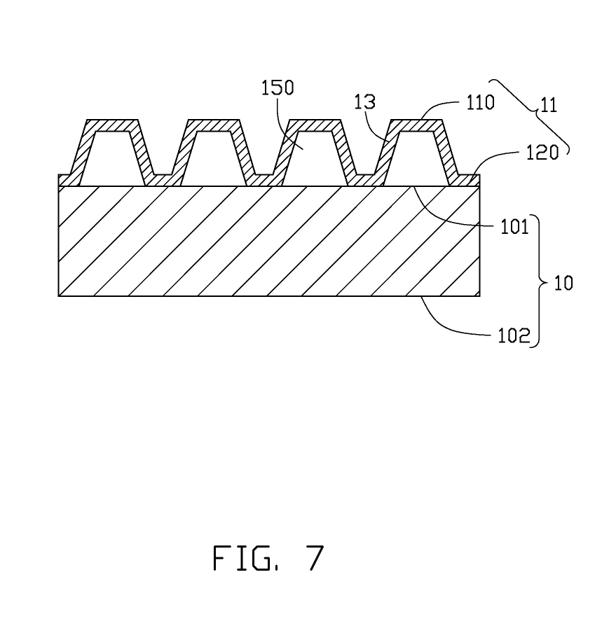

At block 304, referring to FIG. 7, secondly heating the Aluminum nitride layer 13 to separate the protrusions 12 from the Aluminum nitride layer 13 for forming a microstructure 11 with a void gap 150 in the Aluminum nitride layer 13. The microstructure 11 includes a plurality of protruding portions 110 and a plurality of connecting portions 120 connecting to the protruding portion 110. Each void gap 150 is surrounded by a corresponding protruding portion 110. The secondly heating temperature is between 1000° and 12050°, the secondly heating time is between 7 hours and 11 hours. In one example, the secondly heating temperature is 1150°, the secondly heating time is 9 hours.

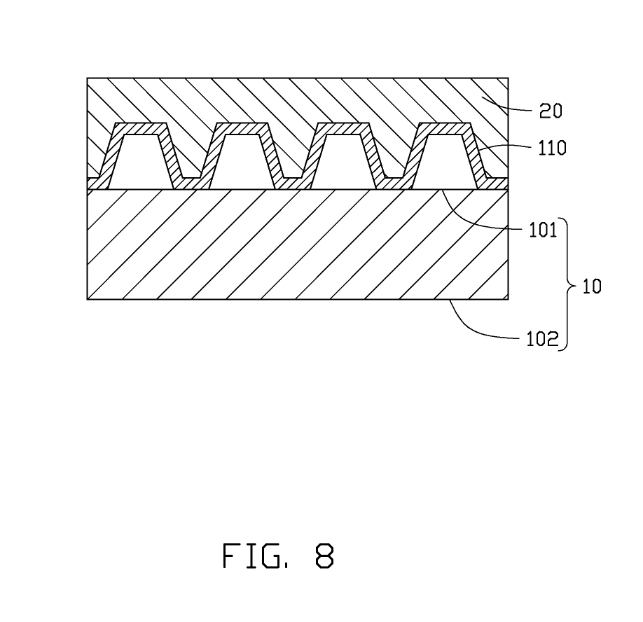

At block 305, referring to FIG. 8, forming a buffer layer 20 on the microstructure 11 to obtain the base 100. The way of forming the buffer layer 20 on the microstructure 11 includes metal organic chemical vapor deposition method, radio frequency magnetron sputtering method, physical vapor deposition method, atomic layer deposition method, or molecular beam deposition method.

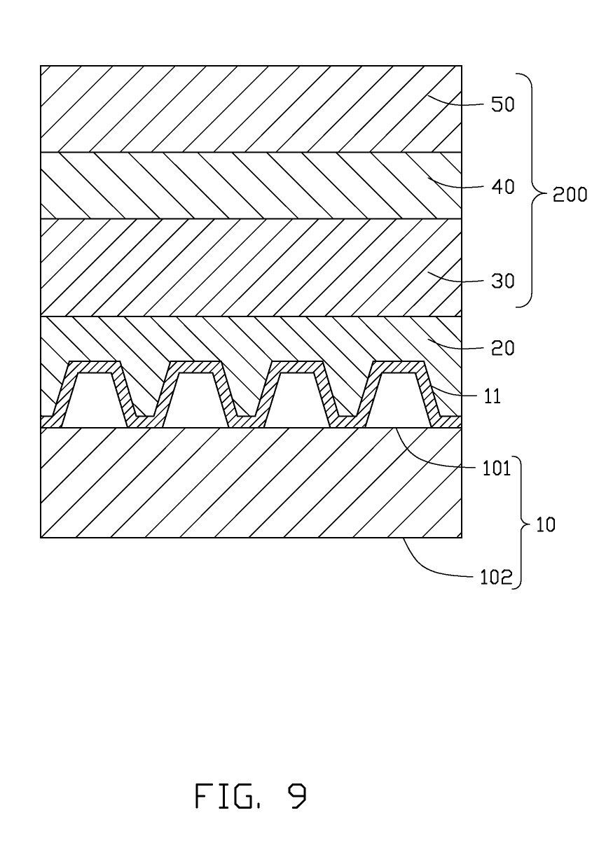

At block 306, referring to FIG. 9, forming a semiconductor structure 200 on the base 100. The way of forming the semiconductor layer 200 on the base 100 includes metal organic chemical vapor deposition method, radio frequency magnetron sputtering method, physical vapor deposition method, atomic layer deposition method, or molecular beam deposition method.

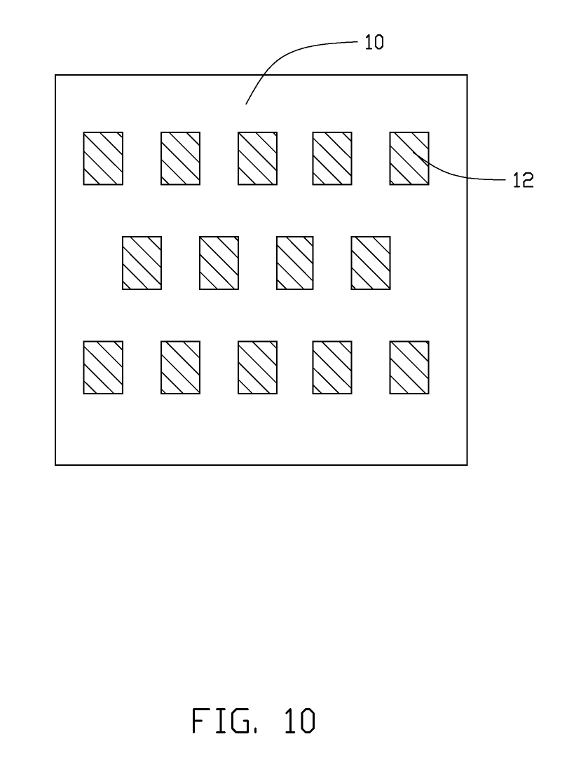

As illustrated in FIG. 10, the protrusions 12 of the FIG. 4 are multiple strips distributed discontinuously.

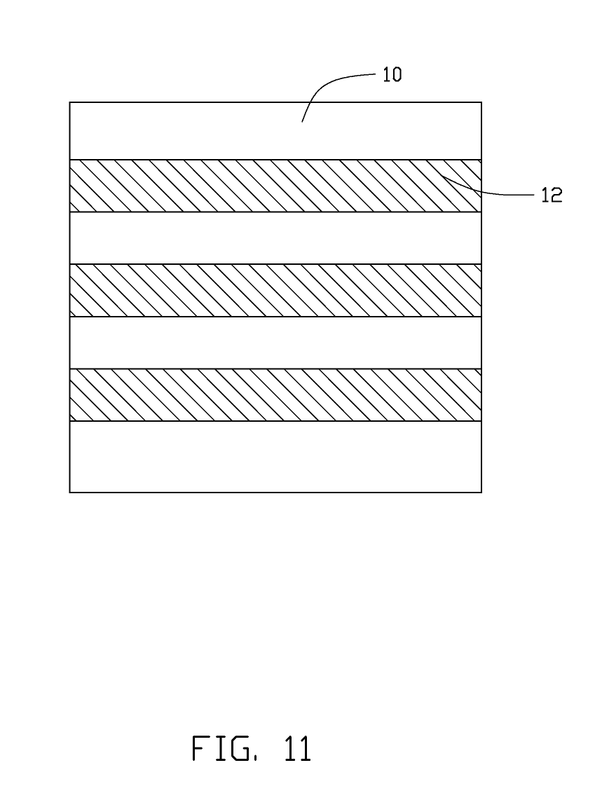

As illustrated in FIG. 11 a plurality of protrusions 12 of a second embodiment of a method for manufacturing the LED. The method for manufacturing the LED of the second embodiment is similar to that of the first embodiment, the difference is that the protrusions are multiple strips distributed continuously.

The embodiments shown and described above are only examples. Many details are often found in the art such as the other features of a light emitting diode and method for manufacturing the same. Therefore, many such details are neither shown nor described. Even though numerous characteristics and advantages of the present technology have been set forth in the foregoing description, together with details of the structure and function of the present disclosure, the disclosure is illustrative only, and changes can be made in the detail, including in matters of shape, size and arrangement of the parts within the principles of the present disclosure up to, and including the full extent established by the broad general meaning of the terms used in the claims. It will therefore be appreciated that the embodiments described above can be modified within the scope of the claims.

What is claimed is:

1. A light emitting diode, comprising:
a base including a substrate;
a semiconductor structure mounted on the base;
the substrate including a first surface and a second surface located opposite to the first surface;
wherein the first surface of the substrate forms a microstructure covering the first surface, the microstructure is a strip bended continuously, and includes a plurality of protruding portions.

2. The light emitting diode of claim 1, wherein a plurality of void gaps are sandwiched between the microstructure and the substrate, each void gap is surrounded by a corresponding protruding portions and the substrate.

3. The light emitting diode of claim 2, wherein each protruding portion includes a top wall and two side walls extending outward and downward form the top wall, each side walls is a flat plate and each void gap is defined by the top wall and two side walls.

4. The light emitting diode of claim 3, wherein the microstructure further includes a connecting portion, each bottom end of the side walls connects with a corresponding connecting portion, the connecting portions are coplanar with each other.

5. The light emitting diode of claim 1, wherein the top walls of the protruding portions are coplanar with each other and a size of the protruding portion decreases from the first surface.

6. The light emitting diode of claim 1, wherein two adjacent side walls and one connecting portion therebetween define a groove.

7. The light emitting diode of claim 6, further comprising a buffer layer, and the buffer layer is filled in the groove and covers the microstructure.

8. The light emitting diode of claim 1, wherein the microstructure having a thickness along a length direction thereof is uniform.

9. The light emitting diode of claim 8, wherein the thickness is between 80 nm and 100 nm.

10. The light emitting diode of claim 1, wherein the semiconductor structure comprising an N semiconductor layer, a light emitting layer, a P semiconductor layer arranging on the base in series, an N electrode is mounted on the N semiconductor, and a P electrode is mounted on the P semiconductor layer.

11. A method for manufacturing the light emitting diode, comprising:
providing a substrate and forming a plurality of protrusions on a first surface of the substrate;
forming a Aluminum nitride layer on the first side of the protrusions and the first surface;
firstly heating the Aluminum nitride layer to make the Aluminum nitride layer crystallized;
secondly heating the Aluminum nitride layer to separate the protrusions from the Aluminum nitride to form a microstructure;
forming a buffer layer on the microstructure to obtain a base; and
forming a semiconductor structure on the base.

12. The method of claim 11, wherein the Aluminum nitride layer can be a strip bended continuously, a thickness of the Aluminum nitride layer is uniform and between 80 nm and 180 nm.

13. The method of claim 11, wherein firstly heating temperature is between 700° and 950°, and the firstly heating time is between 70 minutes and 100 minutes.

14. The method of claim 11, wherein secondly heating temperature is between 1000° and 1250°, and the secondly heating time is between 7 hours and 11 hours.

15. The method of claim 11, wherein the protrusions are multiple strips distributed discontinuously.

16. The method of claim 11, wherein the protrusions are multiple strips distributed continuously.
